(19) United States
(12) Patent Application Publication
(10) Pub. No.: US 2021/0332494 A1
(43) Pub. Date: Oct. 28, 2021

(54) PLATING DEVICE

(71) Applicant: CHEMITRON INC., Tokyo (JP)

(72) Inventors: Katsuaki FUJIMORI, Tokyo (JP); Yoshio NAKAYAMA, Tokyo (JP); Tetsuya KATANIWA, Tokyo (JP); Masanori AKIYAMA, Tokyo (JP)

(73) Assignee: CHEMITRON INC., Tokyo (JP)

(21) Appl. No.: 16/624,807

(22) PCT Filed: Dec. 21, 2018
(86) PCT No.: PCT/JP2018/047296

§ 371 Date: Dec. 19, 2019

(30) Foreign Application Priority Data
Jul. 5, 2018 (JP) 2018-128180

(51) Int. Cl. C25D 17/28; C25D 17/08; C25D 17/02; C25D 17/00; C25D 7/12; H01L 31/18

(52) U.S. Cl. CPC C25D 17/28; C25D 17/08; H01L 31/188; C25D 17/002; C25D 7/12; C25D 17/02

(57) ABSTRACT

A belt conveyer 7 includes a metal belt-shaped conveyer main body 9 and a metal clip 8 held on the conveyer main body 9, and clamps an end part on one side of a work 14 by the spring force of the metal clip 8. A roller conveyer 6 includes multiple conveying rollers 10 that rotate in synch with the belt conveyer 7 and supports the work 14 from below where an end part on the other side of the work 14 clamped by the belt conveyer 7 is placed on the plurality of conveying rollers. The work 14 is conveyed in a horizontal position and is subjected to plating, with the end part on the one side of the work 14 clamped by the belt conveyer 7 and end part on the other side of the work 14 placed on the roller conveyer 6.

### TECHNICAL FIELD

The present invention relates to a plating device for plating a planar work such as a silicon wafer to be used for a silicon solar cell for solar power generation, for example.

### BACKGROUND ART

Patent Document 1 describes a solar cell manufacturing method, which prepares silicon-contained glass substrates having a conductive material on at least one surface, successively conveys at least a part of each substrate in an electrolyte of an electrolytic tank, connects the conductive materials as cathodes while the substrates are being passed through the electrolytic tank, and electrodeposits the material from the electrolyte on the conductive material while being conveyed, and a manufacturing apparatus for the same. The substrates being conveyed are grasped using an elastic clamp element of a conveyer element, and suspended from the conveyer element so as to be extended in the conveyance direction.

Patent Document 2 describes a conveying device for supplying to a surface treatment tank a planar processing object having parallel edges on either side in a horizontal position with the plate sides on top and bottom, successively conveying it in the surface treatment tank horizontally so as to pass through the tank, and carrying it out from the surface treatment tank after surface treatment. Using the conveying device, both sides of the processing object are held at the same time by a group of clamping chucks and then moved in the conveyance direction.

### PRIOR ART DOCUMENTS

### Patent Documents

Patent Document 1: Patent JP 5806613A

Patent Document 2: Patent JP 5283585A

### DISCLOSURE OF THE INVENTION

### Problem to be Solved by the Invention

Generally, in the case of plating a work (substrate) in a plating bath, a plating solution is made to flow by stirring etc. in order to make a uniform plating bath. As a result, if the work is conveyed through the plating bath hanging down vertically with end parts of the work held with clamps (elastic clamp elements) using spring pressure as in Patent Document 1, a moment of force is applied to the end parts (clamping parts) of the work from the flowing plating solution, where the clamping parts of the work having low brittleness may be damaged. Moreover, it is difficult to make properties (concentration, etc.) of the plating solution be completely uniform between an upper part close to the solution surface in the plating bath and a lower part in the solution at a distance from the solution surface, difference in plating thickness generates between the upper side and the lower side of the work, and uniformity of plating thickness may decrease.

On the contrary, in the case of horizontally conveying a work (processing object) as with the device of Patent Document 2, passing the work through a region (on the upper side, for example) having a predetermined height within the plating bath allows uniformity of plating thickness. However, since the end parts (clamping parts) on either side of the work are held by clamps (clamping chuck group), and the work being conveyed is restricted by the clamps from either side, there is a high possibility that the clamping parts of the work having low brittleness are damaged when an unintended external force is applied to the work. Moreover, provision of a conveyance mechanism including clamps on either side of the work is necessary, thereby bringing about complexity and size increase in the device.

Accordingly, the present invention aims to provide a plating device capable of preventing damage of a work during conveyance, and satisfactorily conducting a high-quality plating process.

### Means of Solving the Problem

In order to reach the above aim, a first aspect of the present invention is a plating device for moving a planar work from an upstream side to a downstream side and plating the work, and includes a belt conveyer and a roller conveyer.

The belt conveyer includes a metal belt-shaped conveyer main body and a metal clip held on the conveyer main body and clamps an end part on one side of the work by the spring force of the metal clip. The roller conveyer includes multiple conveying rollers that rotate in sync with the belt conveyer and supports the work from below where an end part on the other side of the work clamped by the belt conveyer is placed on the multiple conveying rollers. The work is conveyed in a horizontal position and is subjected to plating, with the end part on the one side of the work clamped by the belt conveyer and end part on the other side of the work placed on the roller conveyer. The belt conveyer may be capable of clamping the end part on one side of the work between the conveyer main body and the metal clip, and it may be capable of clamping the end part on one side of the work using only the metal clip.

With the above-mentioned structure, since the work is conveyed in a horizontal position, the work is passed through a region at a predetermined height within the plating bath (e.g., upper side), thereby allowing a uniform plating thickness.

Since only an end part on one side and not both sides of the work is clamped by the belt conveyer, and the end part on the other side of the work is placed on the roller conveyer and conveyed, the work is not damaged easily when an unintentional external force is applied to the work being conveyed without being restricted from both sides.

Moreover, the belt conveyer needs to be provided only on one side of the work, thereby allowing suppression of increase in size of the plating device.

A second aspect of the present invention is the plating device of the first aspect, further including a power supply means for applying electric current to the belt conveyer. The belt conveyer negatively charges the work via the work clamping part, which functions as an electric contact and which clamps the work.

With the above-mentioned structure, the work may be negatively charged by applying an electric current from the belt conveyer.

A third aspect of the present invention is the plating device of either the first aspect or the second aspect, further including a plating tank for retaining a plating solution, and an anode arranged in the plating solution retained in the plating tank. At least the bottom surface of the work conveyed in a horizontal position by the belt conveyer and the roller conveyer moves within the plating solution in the plating tank. The anode is an insoluble anode resulting from baking a metal oxide on a metal substrate surface.

With the above-mentioned structure, since insoluble anodes are used, polar ratio (anode/cathode) may be kept constant without wear of anodes due to plating treatment of the work.

A fourth aspect of the present invention is the plating device of the third aspect, further including an ionic permeability neutral diaphragm. The ionic permeability neutral diaphragm divides the plating solution in the plating tank into a first region in which the work moves and a second region in which the anode is arranged, and separates oxygen gas generated from the anode from the plating solution in the first region.

With the above-mentioned structure, since an ionic permeability neutral diaphragm is provided, oxidative decomposition of organic additives within the plating solution due to the oxygen gas generated through electrolysis may be prevented.

### Results of the Invention

According to the present invention, damage of a work during conveyance may be prevented, and a high-quality plating process may be conducted satisfactorily.

### BRIEF DESCRIPTION OF DRAWINGS

FIG. 1 is a side view schematically illustrating a plating device according to a first embodiment of the present invention;

FIG. 2 is a top view of a belt conveyer of the first embodiment;

FIG. 3 is an enlarged view of main parts of the belt conveyer of the first embodiment when viewed from above;

FIG. 4 is a cross section of a plating unit of the plating device;

FIG. 5 is a top view of the plating unit of the plating device;

FIG. 6 is a cross section illustrating an end part on one side of a work clamped by a metal clip according to the first embodiment;

FIG. 7 is a partial cross section illustrating an end part on the other side of the work supported from the bottom by a roller conveyer;

FIG. 8 is a side view of FIG. 7 when viewed in the direction of arrow VIII;

FIG. 9 is a cross section of main parts of the belt conveyer of the first embodiment;

FIG. 10a is a side view of FIG. 9 when viewed in the direction of arrow Xa, and FIG. 10b is a side view of FIG. 9 when viewed in the direction of arrow Xb;

FIG. 11 is a perspective view illustrating the belt conveyer of the first embodiment separated into a conveyer main body and a metal clip;

FIG. 12 illustrates a state of the belt conveyer before clamping the work, wherein

FIG. 12a is a side view and FIG. 12b is a top view;

FIG. 13 illustrates a state of the belt conveyer in the middle of clamping the work using a work attaching part, where FIG. 13a is a side view and FIG. 13b is a top view;

FIG. 14 illustrates a state of the belt conveyer in the middle of clamping the work using the work attaching part, wherein FIG. 14a is a side view and FIG. 14b is a top view;

FIG. 15 illustrates a state of the belt conveyer after clamping the work, wherein FIG. 15a is a side view and FIG. 15b is a top view;

FIG. 16 is a top view schematically illustrating slide movement of the work through the work attaching part;

FIG. 17 is a cross section of a power supply roller;

FIG. 18 is a side view of the power supply roller of FIG. 17 when viewed in the direction of arrow XVIII;

FIG. 19 is a side view of a rotary joint;

FIG. 20 is a top view of a belt conveyer according to a second embodiment;

FIG. 21 is an enlarged view of main parts of the belt conveyer of the second embodiment when viewed from below;

FIG. 22 is a cross section illustrating an end part on one side of a work clamped by a metal clip of the second embodiment;

FIG. 23a is a side view of FIG. 22 when viewed in the direction of arrow XXIIIa, and FIG. 23b is a side view of FIG. 22 viewed in the direction of arrow XXIIIb; and

FIG. 24 is a perspective view illustrating the belt conveyer of the second embodiment separated into a conveyer main body and a metal clip.

### DESCRIPTION OF EMBODIMENTS

A plating device according to a first embodiment of the present invention is described in detail below based on accompanying drawings. Note that left and right directions in the following description mean left and right directions when viewed from upstream to downstream in a conveyance direction 30 of a work 14.

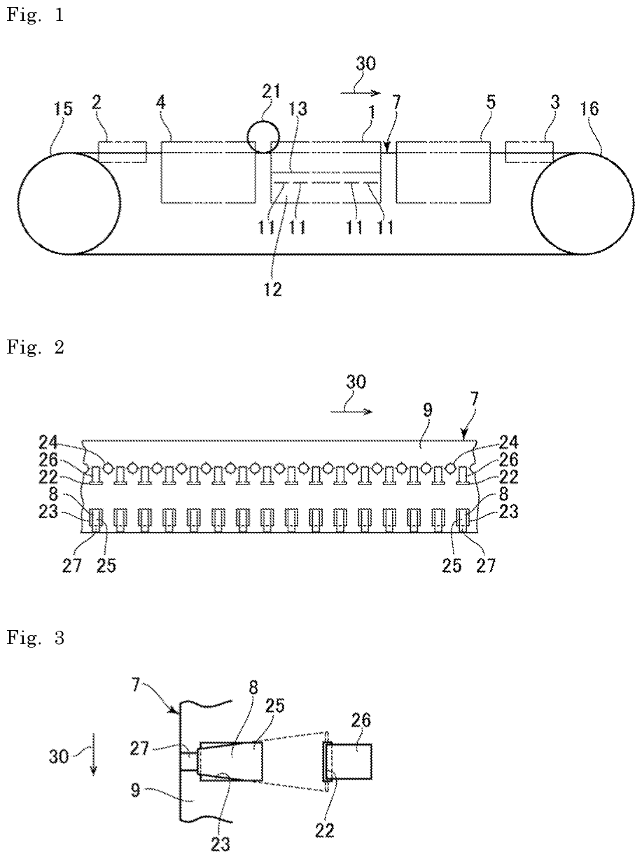

As shown in FIGS. 1, 4, and 5, a plating device according to this embodiment includes a work attaching part 2, a pre-treatment part 4, a plating unit 1, a post-treatment part 5, and a work detaching part 3 when viewed from an upstream side to a downstream side in the conveyance direction 30. Thin planar works 14 are conveyed by belt conveyers 7 and a roller conveyer 6 with the planar works maintained in a horizontal position intersecting the vertical direction at an approximate right angle, and an upstream end and a downstream end of the belt conveyer 7 are wound around a head pulley (driven pulley) 15 and a tail pulley (driving pulley) 16, respectively. The belt conveyer 7 is moved by a driving rotation of the tail pulley 16, and each element of the plating device is supported by a device frame 40. Note that the plating device of this embodiment is provided with two conveyance lines on left and right sides, wherein the left and right conveyance lines are structured approximately symmetrical. Works 14 are successively placed on the respective left and right conveyance lines and conveyed.

The work 14 is a quadrilateral thin-planar (e.g., plate thickness is 0.1 to 0.2 mm) substrate, such as a square silicon wafer made of a vitreous non-metal material, for example. This type of substrate is used for manufacturing solar cells, for example, and is characteristic of being very fragile and easily damaged. Note that while the bottom surface of the work 14 is plated by the plating device of this embodiment, the work 14 and the plating device may be structured such that both the upper and lower surfaces of the work 14 are plated.

Revolving shafts of the head pulley 15 and the tail pulley 16 are respectively extending approximately in the horizontal direction, and the upper part and the lower part of the belt conveyer 7 face each other in the region between the head pulley 15 and the tail pulley 16. The head pulley 15 is arranged on the upstream side of the work attaching part 2, the tail pulley 16 is arranged on the downstream side of the work detaching part 3, and the works 14 are conveyed so that the upper side region of the entire length of the belt conveyer 7 moving from the head pulley 15 toward the tail pulley 16 passes through the work attaching part 2, the pre-treatment part 4, the plating unit 1, the post-treatment part 5, and the work detaching part 3.

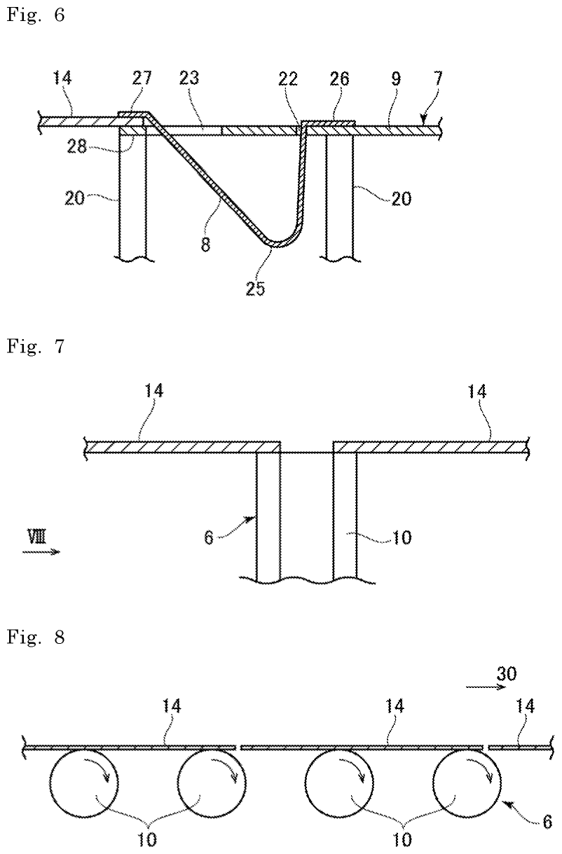

The belt conveyer 7 is provided on either outer side of the left and right conveyance lines (left side part of the left conveyance line, right side part of the right conveyance line), and the left and right belt conveyers 7 are respectively configured with a metal, endless-belt shaped conveyer main body 9 and multiple metal clips 8 held on the conveyer main body 9. The belt conveyers 7 respectively clamp an end part of one side of the work 14 (left end part of the work 14 on the left conveyance line, right end part of the work 14 on the right conveyance line) between tip movable piece parts 27 of the metal clips 8 and a belt end part 28 of the conveyer main body 9 (see FIG. 6). Details of the belt conveyer 7 are given later.

The roller conveyer 6 is arranged on either inner side of the left and right conveyance lines (right side part of the left conveyance line, left side part of the right conveyance line) and shared by the left and right conveyance lines. The roller conveyer 6 has multiple conveying rollers 10, which are provided at predetermined intervals in the conveyance direction 30 and fixed to respective roller shafts 17 approximately orthogonal to the conveyance direction 30, and the roller shafts 17 are supported rotatably on the device frame 40. Sprockets 19 engaged with a roller chain 18 are fixed to an end part (right end part in this embodiment) of the roller shafts 17, and the roller shafts 17 and the roller conveyers 6 (conveying rollers 10) are rotated by the roller chain 18 in sync with the conveying speed of the belt conveyer 7. As shown in FIGS. 7 and 8, left side parts of the outer peripheral surface of the roller conveyers 6 (conveying rollers 10) make contact with the bottom surface of the right end part of the work 14 on the left conveyance line so as to support the right end part (end part on the other side) of the work 14 on the left conveyance line from underneath. Similarly, right side parts on the outer peripheral surface of the roller conveyers 6 (conveying rollers 10) make contact with the bottom surface of the left end part of the work 14 on the right conveyance line so as to support the left end part (end part on the other side) of the work 14 on the right conveyance line from underneath.

Left and right belt holding rollers 20, which make contact with the bottom surfaces of the left and right belt conveyers 7 to support them from underneath, are fixed to the roller shaft 17 (see FIG. 17). Moreover, upstream side and downstream side conveyer rollers (omitted from the drawings) that are rotated by the roller chain 18 are provided on the upstream side of the work attaching part 2 and the downstream side of the work detaching part 3, respectively. The work 14 before being clamped by the belt conveyers 7 is conveyed to the work attaching part 2 by the conveying rollers on the upstream side, and the work 14 detached from the belt conveyers 7 is conveyed from the work detaching part 3 by the conveyer rollers on the downstream side.

As shown in FIGS. 1 and 17, a power supply roller (power supply means) 21 for applying an electric current from a rectifier (omitted from the drawings) to the belt conveyers 7 is provided on the plating device. The power supply roller 21 of this embodiment is arranged on or near the plating unit 1. The belt conveyers 7 are negatively charged by an electric current (plating current) applied from the power supply roller 21, and negatively charge the work 14 via work clamping parts (the tip movable piece parts 27 of the metal clips 8 and the belt end part 28 of the conveyer main body 9 described later) which functions as electric contacts and clamp the work 14 using the spring force of the metal clips 8. Details of the power supply roller 21 are given later.

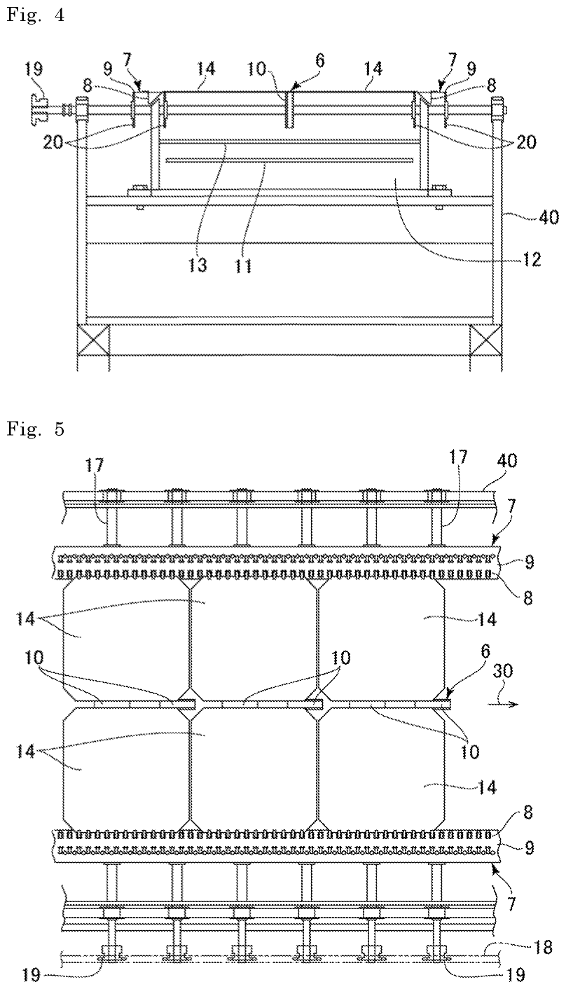

As shown in FIGS. 4 and 5, an end part on one side (left end part for the left conveyance line, right end part for the right conveyance line) of the work 14 is clamped by the metal clips 8, which are installed on the belt conveyers 7, on the work attaching part 2 so as to be moved, and end part on the other side (right end part for the left conveyance line, left end part for the right conveyance line) of the work 14 is placed on the roller conveyers 6 so as to be moved. As a result, the work 14 is moved to the work detaching part 3 (conveyed horizontally) passing through the pre-treatment part 4, the plating unit 1, and the post-treatment part 5 while maintaining a horizontal position (horizontal state) approximately orthogonal to the vertical direction. Nearly throughout the conveyance path from the work attaching part 2 to the work detaching part 3, top and bottom surfaces of the work 14 in the region between the end part on one side and the end part on the other side are exposed extensively.

The pre-treatment part 4 illustrated in FIG. 1 is provided with multiple pre-treatment tanks (omitted from the drawing), wherein immersion treatments are carried out for the work 14 by making the work 14 pass through each treatment tank. The pre-treatment part 4 cleans the surface of the work 14 including the steps of degreasing, rinsing, and soaking in an acidic solution to remove impurities.

The plating unit 1 moves the work 14, which has been moved from the pre-treatment part 4, downstream in a horizontal position so as to carry out electroplating on the work 14. As shown in FIGS. 1 and 4, a plating tank 12, insoluble anodes 11, and an ionic permeability neutral diaphragm 13 are provided on the plating unit 1, wherein a plating solution (e.g., a copper sulfate plating solution in the case of copper sulfate plating) is cyclically supplied to the plating tank 12 and retained. As an example, a plating solution is sent to the plating tank 12 from a control tank (omitted from the drawings) via a pump (omitted from the drawings), and the plating solution higher than a predetermined solution surface is overflowed and returned downstream to the control tank due to difference in elevation.

The solution surface of the plating solution within the plating tank 12 (plating bath) is set such that at least the bottom surface of the work 14 to be conveyed is moved near the solution surface within the plating solution. Note that in the case of plating both the top and bottom surfaces of the work 14, the solution surface in the plating bath should be set so that the top surface of the work 14 is moved near the solution surface within the plating solution.

As described above, the belt conveyers 7 negatively charge the work 14 by applying an electric current from the power supply roller 21 via the work clamping parts 27 and 28 which functions as electric contacts.

The insoluble anodes 11 are formed on a metal substrate surface made of titanium or the like by baking a metal oxide such as iridium oxide, and are arranged at the bottom of the plating bath so as to face the bottom surface of the work 14. In this embodiment, multiple insoluble anodes 11 are provided in the conveyance direction 30, and copper plating is conducted on the work 14 by connecting anodes (omitted from the drawings) to the insoluble anodes 11. Note that making the electric current applied to the plurality of insoluble anodes 11 be higher gradually from the upstream side toward the downstream side allows suppression of rapid increase in load applied to the work due to plating, and prevention of cracks (damage) in the work 14.

The ionic permeability neutral diaphragm 13 is arranged between the conveying region of the work 14 and the insoluble anodes 11 so as to separate the plating solution into an upper layer (first region) in which the work 14 is moved and a lower layer (second region) in which the insoluble anodes 11 are arranged. Copper oxide powder is used as a plating metal supply source, and oxygen gas generated from the insoluble anodes 11 is separated from the plating solution in the upper layer by the ionic permeability neutral diaphragm 13.

In this manner, since the insoluble anodes 11 are used, polar ratio (anode/cathode) may be kept constant without wear of anodes during the production process (plating treatment of the work 14). Accordingly, copper ions may be supplied offline during the production process without exchanging the anodes during the production process.

Moreover, since the ionic permeability neutral diaphragm 13 is provided, oxidative decomposition of organic additives within the copper sulfate plating solution due to the oxygen gas generated through electrolysis may be prevented, and it is effective for maintaining and stabilizing plating performance.

The post-treatment part 5 carries out rinsing, rust prevention, and dewatering and drying while conveying the work 14 in a horizontal position, and the top surface of the work 14 that has been moved from the plating unit 1 is cleaned and then dried.

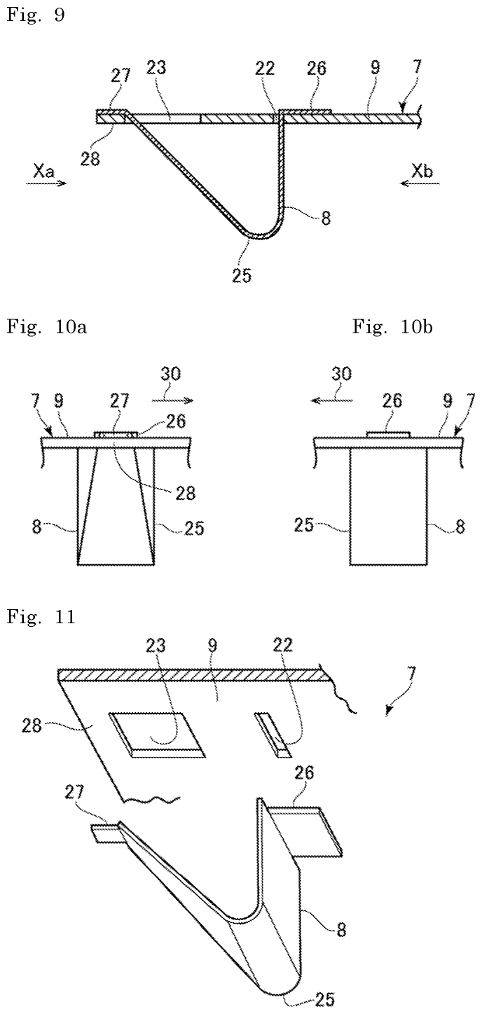

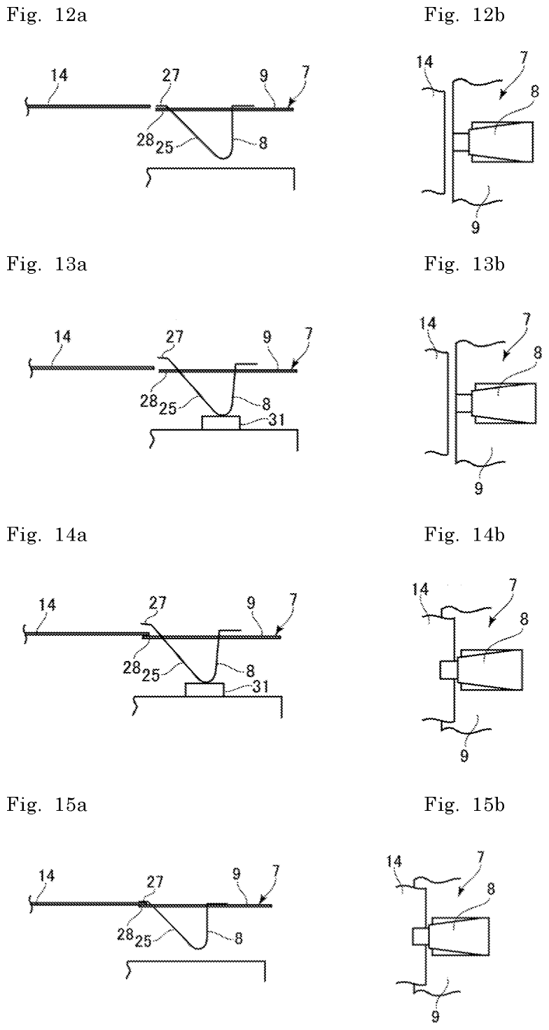

Next, the belt conveyer 7 is described while referencing FIGS. 2, 3, 6, and 8 to 11.

The belt conveyer 7 is structured by assembling multiple metal clips 8 on the metal, endless-belt shaped conveyer main body 9. On the conveyer main body 9, multiple rectangular clip engaging holes 22, rectangular clip inserting holes 23 larger than the clip engaging holes 22, and circular power supply engaging holes 24 are formed at predetermined intervals (at equal intervals), respectively, in the conveyance direction 30. The clip inserting holes 23 are arranged between an end on one side (inner side) of the conveyer main body 9 and the clip engaging holes 22, and the clip engaging holes 22 and the clip inserting holes 23 are lined up separated in pairs along the width (direction approximately orthogonal to the conveyance direction 30) of the conveyer main body 9. The power supply engaging holes 24 are arranged on the outer side of the clip engaging holes 22.

The metal clip 8 is an integrated body including a bending portion 25 bending in a U-shape, and a locking piece 26 and the tip movable piece part 27, which extend from the one end and the other end of the bending portion 25 in the opposite direction to each other, and is formed by punching a metal plate having elasticity (spring force) and bending it in a predetermined shape. The plate width of the bending portion 25 is approximately the same width from the apex of the bending portion 25 to the locking piece 26, and tapers off as it approaches the tip movable piece part 27 in the region from the apex of the bending portion 25 to the tip movable piece part 27. Width of the end of the bending portion 25 adjacent to the locking piece 26 is wider than the clip engaging hole 22, and width of the adjacent region of the bending part 25 to the tip movable piece part 27 is narrower than the clip inserting hole 23. Width of the locking piece 26 is narrower than the clip engaging hole 22, and width of the tip movable piece part 27 is narrower than the clip inserting hole 23. Distance between the locking piece 26 and the tip movable piece part 27 is set longer than the maximum distance between the clip engaging hole 22 and the clip inserting hole 23, and the metal clip 8 is assembled on the conveyer main body 9 by inserting the locking piece 26 in the clip engaging hole 22 and inserting the tip movable piece part 27 through the clip inserting hole 23 while elastically deforming the bending portion 25. The assembled state of the metal clip 8 is maintained by the elasticity (spring force) of the bending portion 25, and in the clip assembled state, the tip movable piece part 27 of the metal clip 8 comes close to or makes contact with the surface of the region (belt end part 28) between the inner side end of the conveyer main body 9 and the clip inserting hole 23. Note that according to this embodiment, the belt conveyer 7 is wound around the head pulley 15 and the tail pulley 16 (see FIG. 1) along the conveyance path of the work 14 so that the bending portion 25 of the metal clip 8 protrudes downward from the conveyer main body 9.

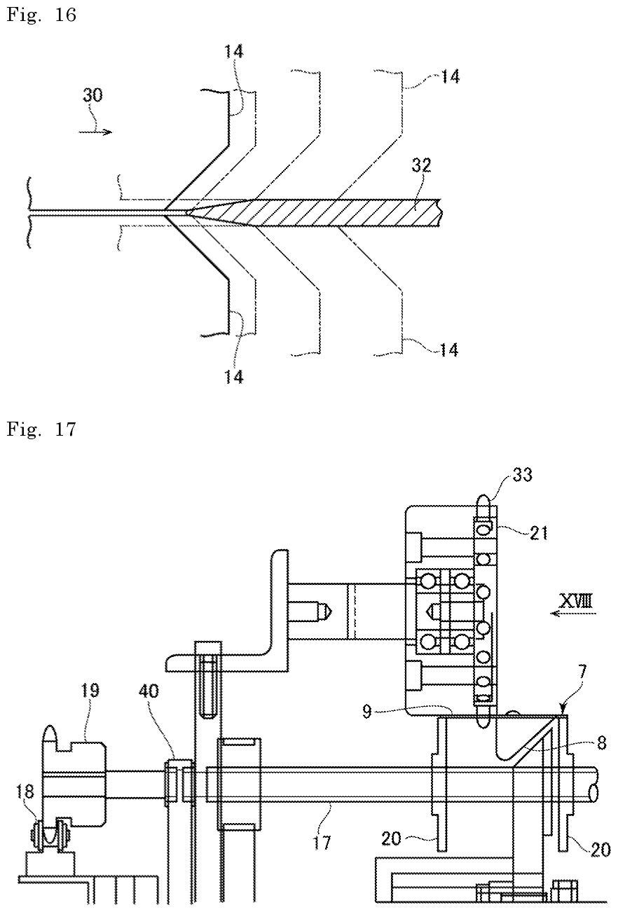

The works 14 are fed to the work attaching part 2 (see FIG. 1) such that they are lined up on nearly the same plane as that of the conveyer main body 9 of the belt conveyers 7 (see FIG. 12). The work attaching part 2 pushes up the bending portion 25 using a clip pushing part 31 such as an actuator supported by the device frame 40, thereby separating the tip movable piece part 27 of the metal clip 8 from the belt end part 28 of the conveyer main body 9 (see FIG. 13). Next, with the tip movable piece part 27 separated from the belt end part 28, the work 14 is slid and moved to the belt conveyer 7 side and the end part of the work 14 is inserted between the tip movable piece part 27 and the belt end part 28 (see FIG. 14). Slide movement of the work 14 is carried out by sliding the end of the work 14 to be conveyed, for example, to a work guiding part 32 supported by the device frame 40 so as to change the moving direction of the work 14 (see FIG. 16). The pushing up of the bending portion 25 by the clip pushing part 31 is then released with the end part of the work 14 inserted between the tip movable piece part 27 and the belt end part 28. As a result, the bending portion 25 is restored, and the end part of the work 14 is clamped between the tip movable piece part 27 and the belt end part 28 due to the spring force of the metal clip 8. Multiple metal clips 8 are installed on the belt main body 9 such that a single work 14 is clamped at multiple places. The work 14 is moved from the work attaching part 2 to the work detaching part 3 with the end on one side of the work clamped by the belt conveyers 7. The work detaching part 3 releases the work 14 clamped by the belt conveyers 7 through the reverse process (procedure) of the work attaching part 2.

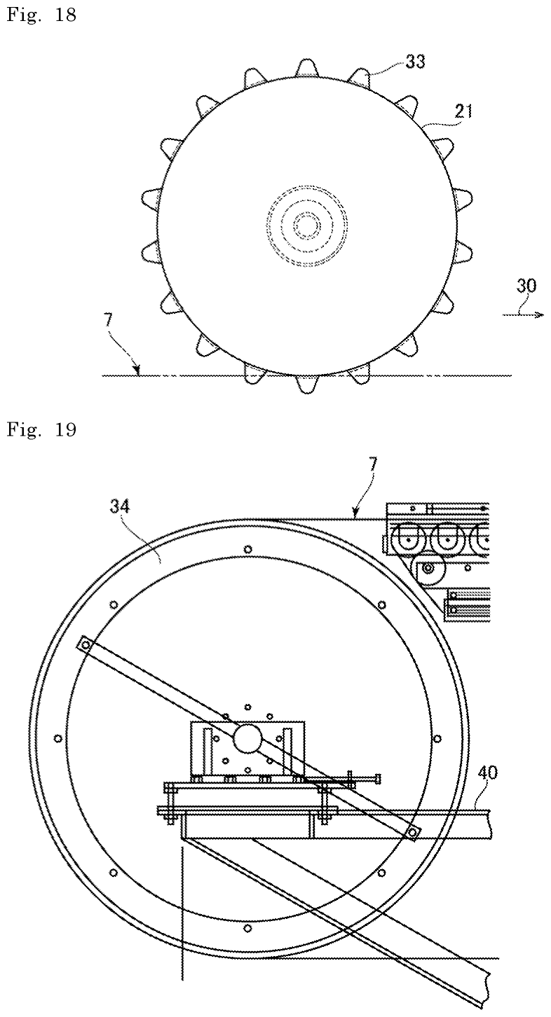

Next, the power supply roller 21 is described while referencing FIGS. 17 and 18.

The power supply roller 21 is arranged above the belt conveyers 7, and is rotatably supported by the device frame 40. From the outer peripheral surface of the power supply roller 21, multiple engageable protrusions 33 inserted in the power supply engaging holes 24 (see FIG. 2) of the belt main body 9 protrude at the same intervals as those of the power supply engaging holes 24. The power supply roller 21 is rotated in sync with the movement of the belt conveyers 7 so that the protrusions 33 are successively engaged and disengaged with the power supply engaging holes 24, and the outer peripheral surface of the power supply roller 21 is always in surface contact with the top surface of the belt main body 9. Relative positions of the belt conveyers 7 to the power supply roller 21 are regulated within a desired range according to the engaging of the protrusions 33 with the power supply engaging holes 24. A rectifier (omitted from the drawings) is connected to the power supply roller 21, so as to apply a plating current to the belt conveyers 7 from the rectifier via the power supply roller 21.

Note that a rotary joint (power supply means) 34 as illustrated in FIG. 19 may be provided instead of the power supply roller 21. The rotary joint 34 is a member having both a function as a pulley around which the belt conveyer 7 is wound and a function of applying a plating current to the belt conveyer 7. Therefore, the rotary joint 34 may be provided in place of either the head pulley 15 or the tail pulley 16 (see FIG. 1).

According to the plating device of this embodiment, the work 14 in a horizontal position passes through a region (upper side) at a predetermined height within the plating bath, thereby allowing generation of a uniform plating thickness.

Since only an end part on one side and not both sides of the work 14 is clamped by the belt conveyers 7, and an end part on the other side of the work 14 is placed on the roller conveyer 6 and conveyed, the work 14 is not restricted from both sides, and the work 14 is thus not damaged easily even when an unintentional external force is applied to the work 14.

Since the belt conveyer 7 needs to be provided only on one side of the work 14, suppression of increase in size of the plating device is possible.

Since the roller conveyer 6 supporting the left and right end parts of the work 14 from below is shared by the left and right conveying lines, increase in width of the plating device may be controlled.

Moreover, a plating current may be applied to the work 14 from the belt conveyer 7 so as to negatively charge the work 14.

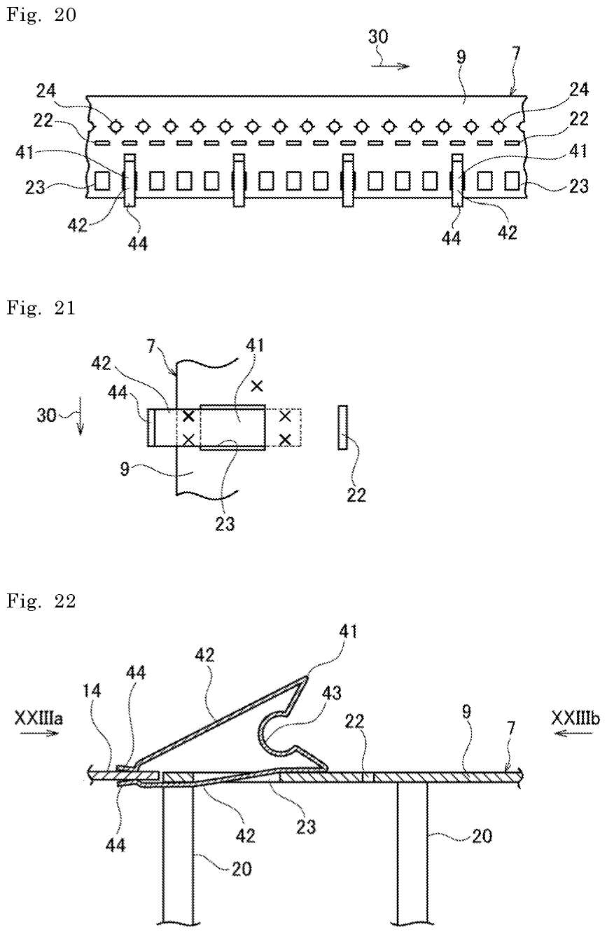

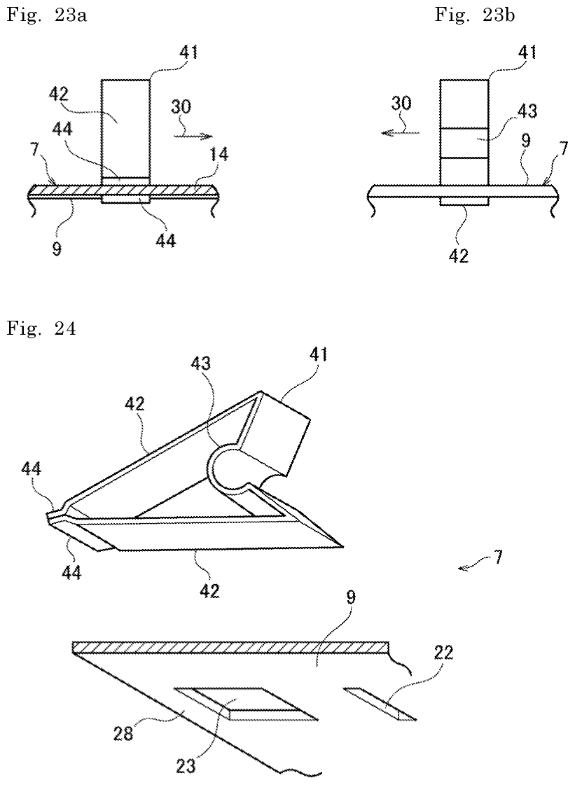

Next, a second embodiment of the present invention is described while referencing FIGS. 20 to 24. Since the structure of metal clips 41 according to this embodiment differs from that of the first embodiment (metal clips 8) but other components are the same, the same reference numerals are given to the common components and description thereof is omitted. Note that while the clip engaging holes 22 are formed in the conveyer main body 9 according to this embodiment because the same conveyer main body 9 of the first embodiment is used, the clip engaging holes 22 may be omitted entirely in this embodiment. Moreover, according to this embodiment, there are fewer of the metal clips 41 fixed to the conveyer main body 9 as described later than in the first embodiment, and thus there are some clip inserting holes 23 in which metal clips 41 are not inserted. However, the clip inserting holes 23 in which metal clips 41 are not inserted may be omitted. Furthermore, the clip inserting holes 23 function only for positioning in order to arrange the metal clips 41 at equal intervals, and therefore in the case where positioning the metal clips 41 using the clip inserting holes 23 is unnecessary (for example, when the metal clips 41 can be fixed at predetermined locations on the conveyer main body 9 using a different method), the clip inserting holes 23 may be completely omitted.

The metal clip 41 has an integrated body including a pair of planar clip bases 42, one above the other and facing each other at a distance, and a spring part 43 connecting an end of each of the clip bases 42, and is formed by punching a metal plate having elasticity (spring force) and bending it in a predetermined shape. The plate width of the clip base 42 is approximately the same from one end side to the other end side, and is slightly narrower than the clip inserting hole 23. The other respective ends of the clip bases 42 configure work clamping parts 44, wherein upper and lower work clamping parts 44 are urged in the direction of approaching each other due to elasticity (spring force) of the spring part 43. By pushing the one end sides of the upper and lower clip bases 42 in the direction of approaching each other against the spring force of the spring part 43, the upper and lower work clamping parts 44 separates from each other and open up, and by inserting an object (e.g., edge part on one end of the work) between the opened-up upper and lower work clamping parts 44, and then releasing the pushing of the clip bases 42, the upper and lower clamping parts 44 close due to the spring force of the spring part 43, thereby clamping the object.

The metal clips 41 are held on the conveyer main body 9 by inserting the work clamping part 44 on the lower side of clip base 42 into the clip inserting hole 23 from above, and fixing the lower clip base 42 on the conveyer main body 9 with the lower and upper work clamping parts 44 protruding from the belt end part 28. According to this embodiment, the lower clip base 42 and the conveyer main body 9 are spot welded at a total of four places: two places where the lower clip base 42 overlaps the conveyer main body 9 from above, and two places where the lower clip base 42 overlaps the conveyer main body 9 from below (welded places in FIG. 21 are indicated by X.) Note that while according to the first embodiment, the metal clips 8 are assembled for all of the clip inserting holes 23, the metal clips 41 are assembled for every fourth hole (leaving open three consecutive clip inserting holes 23) according to this embodiment. Along the conveyance path of the work 14, the belt conveyers 7 are wound around the head pulley 15 and the tail pulley 16 (see FIG. 1) such that the spring parts 43 of the metal clips 41 and the upper clip base 42 protrude upward from the conveyer main body 9. The metal clips 41 may be fixed on the conveyer main body 9 such that the spring parts 43 and the lower clip base 42 protrude downward from the conveyer main body 9 along the conveyance path of the work 14. Moreover, the method of fixing the metal clips 41 on the conveyer main body 9 is not limited to welding, and another method may be used. Furthermore, the metal clips may be held on the conveyer main body by forming the metal clips and the conveyer main body as an integrated body.

While according to the first embodiment, the end part on one side of the work 14 is clamped between the tip movable piece parts 27 of the metal clips 8 and the belt end part 28 of the conveyer main body 9 (see FIG. 6), the end part on one side of the work 14 is clamped between the upper and lower work clamping parts 44 of the metal clips 41 (see FIG. 22) according to this embodiment. Moreover, as in the first embodiment, the belt conveyer 7 is negatively charged by applying an electric current (plating current) from the power supply roller 21, and the work 14 is negatively charged via the work clamping parts 44, which functions as electric contacts.

The present invention has been described above based on the above embodiments; however, the present invention is not limited to the contents of these embodiments, and appropriate modifications thereof are naturally possible within the scope of the invention. For example, while a plating device including the pre-treatment part 4 and the post-treatment part 5 is described according to the embodiments described above, a plating device not including one or both may be used.

The form (including form of the tip movable piece parts 27 of the metal clips 8, form of the work clamping part 44 of the metal clip 41, and/or form of the belt end part 28 of the conveyer main body 9) of the belt conveyer 7 (the metal clips 8 and 41 and the conveyer main body 9) is not limited to the above embodiments, as long as the work 14 has a form allowing it to be clamped by either between the metal clips 8 and the belt main body 9 or by only the metal clips 41.

Moreover, the power supply means is not limited to the power supply roller 21 and the rotary joint 34, and may take another form.

### INDUSTRIAL APPLICABILITY

The present invention may be widely used as a device for plating a planar work.

### EXPLANATION OF REFERENCES

1: Plating unit
2: Work attaching part
3: Work detaching part
4: Pre-treatment part
5: Post-treatment part
6: Roller conveyer
7: Belt conveyer
8, 41: Metal clip
9: Conveyer main body
10: Conveying roller
11: Insoluble anode
12: Plating tank
13: Ionic permeability neutral diaphragm
14: Work
15: Head pulley (driven pulley)
16: Tail pulley (driving pulley)
17: Roller shaft
18: Roller chain
19: Sprocket
20: Belt holding roller
21: Power supply roller (power supply means)
22: Clip engaging hole
23: Clip inserting hole
24: Power supply engaging hole
25: Bending portion
26: Locking piece
27: Tip movable piece part (work clamping part)
28: Belt end part (work clamping part)
30: Conveyance direction
31: Clip pushing part
32: Work guiding part
33: Protrusion
34: Rotary joint (power supply means)
40: Device frame
42: Clip base
43: Spring part
44: Work clamping part

1. A plating device for moving a planar work from an upstream side to a downstream side and plating the work, comprising:
a belt conveyer that comprises a metal belt-shaped conveyer main body and a metal clip held on the conveyer main body and clamps an end part on one side of the work by the spring force of the metal clip; and
a roller conveyer comprising a plurality of conveying rollers that rotates in sync with the belt conveyer and supports the work from below where an end part on the other side of the work clamped by the belt conveyer is placed on the plurality of conveying rollers; wherein
the work is conveyed in a horizontal position and is subjected to plating, with the end part on the one side of the work clamped by the belt conveyer and end part on the other side of the work placed on the roller conveyer.

2. The plating device of claim 1, further comprising:
a power supply for applying electric current to the belt conveyer, wherein
the belt conveyer negatively charges the work via a work clamping part, which functions as an electric contact and which clamps the work.

3. The plating device of claim 1, further comprising:
a plating tank for retaining a plating solution; and
an anode arranged in the plating solution retained in the plating tank, wherein
at least the bottom surface of the work conveyed in a horizontal position by the belt conveyer and the roller conveyer moves within the plating solution in the plating tank, and
the anode is an insoluble anode resulting from baking a metal oxide on a metal substrate surface.

4. The plating device of claim 3, further comprising an ionic permeability neutral diaphragm that divides the plating solution in the plating tank into a first region in which the work moves and a second region in which the anode is arranged and that separates oxygen gas generated from the anode from the plating solution in the first region.

5. The plating device of claim 2, further comprising:
a plating tank for retaining a plating solution; and
an anode arranged in the plating solution retained in the plating tank, wherein
at least the bottom surface of the work conveyed in a horizontal position by the belt conveyer and the roller conveyer moves within the plating solution in the plating tank, and
the anode is an insoluble anode resulting from baking a metal oxide on a metal substrate surface.
